(19) United States
(12) Patent Application Publication
(10) Pub. No.: US 2016/0190153 A1
(43) Pub. Date: Jun. 30, 2016

(54) SEMICONDUCTOR DEVICE AND METHOD OF FABRICATING THE SAME

(71) Applicant: MACRONIX International Co., Ltd., Hsinchu (TW)

(72) Inventors: Jung-Yi Guo, Hsinchu (TW); Chun-Min Cheng, Hsinchu (TW)

(21) Appl. No.: 14/582,941

(22) Filed: Dec. 24, 2014

(51) Int. Cl. H01L 27/115; H01L 21/02; H01L 21/3105

(52) U.S. Cl. CPC H01L 27/11582; H01L 27/11568; H01L 21/31055; H01L 21/0228; H01L 21/02164; H01L 21/0217; H01L 21/02282

(57) ABSTRACT

A semiconductor device and a method of fabricating the same are provided. The semiconductor device includes a substrate, a plurality of fin structures, a plurality of conductor liner layers, a charge storage layer, a plurality of first conductor layers, and a plurality of filling pillars. The fin structures are disposed on the substrate, and a trench is formed between two adjacent fin structures. Each of the conductor liner layers covers a portion of sidewalls and a portion of top surfaces of the fin structures. The charge storage layer is disposed between the fin structures and the conductor liner layers. The first conductor layers cover the conductor liner layers and are electrically connected to the conductor liner layers. The filling pillars are disposed in the trenches and between the conductor liner layers and the first conductor layers.

### BACKGROUND OF THE INVENTION

1. Field of the Invention

The invention relates to a semiconductor device and a method of fabricating the same.

2. Description of Related Art

As semiconductor devices are integrated, in order to achieve high density and high performance, it is preferred to form a structure stacked upward when fabricating the semiconductor devices, such that the wafer area can be used more efficiently. Therefore, semiconductor structures having a high aspect ratio are commonly seen in small-sized devices. For example, the semiconductor structure includes trenches with a high aspect ratio, for example.

Generally speaking, fabrication of the device includes filling a conductor layer into the trenches with a high aspect ratio. However, since the conductor layer itself does not have a preferable gap-filling ability, unevenly distributed voids are easily formed in the trenches, resulting in a negative influence on electrical testing of the semiconductor device. Besides, the voids may generate unbalanced stresses at two sides of the trench, thus resulting in microbending of the semiconductor structure between the trenches and consequently making the alignment in a subsequent photolithography process more challenging. Thus, how to prevent voids in the trenches with a high aspect ratio and avoid microbending of the semiconductor structures is certainly an issue to work on.

### SUMMARY OF THE INVENTION

The invention provides a method of fabricating a semiconductor device capable of avoiding microbending of a semiconductor structure.

The invention provides a semiconductor device. The semiconductor device includes a substrate, a plurality of fin structures, a plurality of conductor liner layers, a charge storage layer, a plurality of first conductor layers, and a plurality of filling pillars. The fin structures are disposed on the substrate, and a trench is between two adjacent fin structures. The conductor liner layers are disposed on the substrate. Each of the conductor liner layers covers a portion of sidewalls and a portion of top surfaces of the fin structures. The charge storage layer is disposed between the fin structures and the conductor liner layers. The first conductor layers are disposed on the substrate, cover the conductor liner layers, and are electrically connected with the conductor liner layers on the portion of the top surfaces of the fin structures. The filling pillars are disposed in the trenches and between the conductor liner layers and the first conductor layers.

According to an embodiment of the invention, a surface of the filling pillars is substantially aligned with a surface of the conductor liner layers.

According to an embodiment of the invention, a material of the filling pillars includes silicon nitride, silicon oxide, spin-on-glass (SOG) or a combination thereof

According to an embodiment of the invention, a material of the conductor liner layers and a material of the first conductor layers respectively comprise polysilicon, doped polysilicon, or a combination thereof.

According to an embodiment of the invention, each of the fin structures extends along a first direction, each of the conductor liner layers and each of the first conductor layers extend along a second direction, and the first direction is different from the second direction.

According to an embodiment of the invention, each of the fin structures includes a plurality of second conductor layers and a plurality of dielectric layers alternately disposed with the second conductor layers.

According to an embodiment of the invention, the conductor liner layers and the first conductor layers together serve as word lines or bit lines.

The invention also provides a semiconductor device including a substrate, a plurality of fm structures, a plurality of composite conductor layers, and a plurality of filling pillars. The fin structures are disposed on the substrate, wherein a trench is between two adjacent fin structures. The composite conductor layers are disposed on the substrate. Each of the composite conductor layers covers a portion of sidewalls and a portion of top surfaces of the fin structures. The filling pillars are disposed in the trenches and in each of the composite conductor layers.

According to an embodiment of the invention, a gap-filling ability of the filling pillars is better than a gap-filling ability of the composite conductor layers.

According to an embodiment of the invention, each of the composite conductor layers includes a conductor liner layer and a first conductor layer. The conductor liner layer is disposed on the substrate. Each conductor liner layer covers a portion of the sidewalls and a portion of the top surfaces of the fin structures. The first conductor layer is disposed on the conductor liner layer and electrically connected with the conductor liner layer.

According to an embodiment of the invention, each of the fin structures extends along a first direction, each of the composite conductor layers extends along a second direction, and the first direction is different from the second direction.

According to an embodiment of the invention, the composite conductor layers serve as word lines or bit lines.

The invention provides a method of fabricating a semiconductor device including steps as follows: providing a substrate; forming a plurality of fin structures over the substrate, wherein a trench is between two adjacent fin structures; forming a plurality of conductor liner layers on the substrate, wherein each of the conductor liner layers covers a portion of sidewalls and a portion of top surfaces of the fin structures; forming a charge storage layer between the fin structures and the conductor liner layers; forming a plurality of first conductor layers on the substrate, wherein the first conductor layers cover the conductor liner layers, and are electrically connected with the conductor liner layers on the portion of the top surfaces of the fin structures; forming a plurality of filling pillars in the trenches, wherein the filling pillars are disposed between the conductor liner layers and the first conductor layers.

According to an embodiment of the invention, the steps of forming the conductor liner layers and the first conductor layers on the substrate and forming the filling pillars in the trenches include steps as follows: forming a first conductor material layer on the charge storage layer; forming a plurality of filling layers in the trenches, forming a second conductor material layer on the first conductor material layer and the filling layers; and patterning the first conductor material layer, the filling layers and the second conductor material layer to form the conductor liner layers, the filling pillars and the first conductor layers.

According to an embodiment of the invention, the step of forming the filling layers in the trenches includes forming a filling material layer on the substrate, wherein the filling material layer covers the first conductor material layer; and removing the filling material layer on the top surfaces of the fin structures to form the filling layers in the trenches.

According to an embodiment of the invention, a method of removing the filling material layer on the top surfaces of the fin structures includes performing an etching back process or a chemical mechanical polishing process.

According to an embodiment of the invention, a method of forming the filling material layer comprises performing an atomic layer deposition process or a spin coating process.

According to an embodiment of the invention, a material of the filling pillars comprises silicon nitride, silicon oxide, spin-on-glass (SOG) or a combination thereof

Based on the above, in the invention, the conductor liner layer is formed in the trench having a high aspect ratio, and then the first conductor layer covering the conductor liner layer is formed after filling the filling layer in the trench. Since the filling layer has a better gap-filling ability, it is less likely to produce a void when filling the filling layer in the trench. In addition, the filling layer may serve as a support pillar in the trench to provide a higher resistance, thereby preventing microbending of the semiconductor structure between the trenches.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view illustrating a semiconductor device according to an embodiment of the invention.

FIG. 2 is a schematic cross-sectional view illustrating the semiconductor device along a A-A′ line of FIG. 1.

FIGS. 3A to 3G are schematic cross-sectional views illustrating a method of fabricating a semiconductor device according to an embodiment of the invention.

FIGS. 4A and 4B are schematic cross-sectional views illustrating a method of fabricating a semiconductor device according to another embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

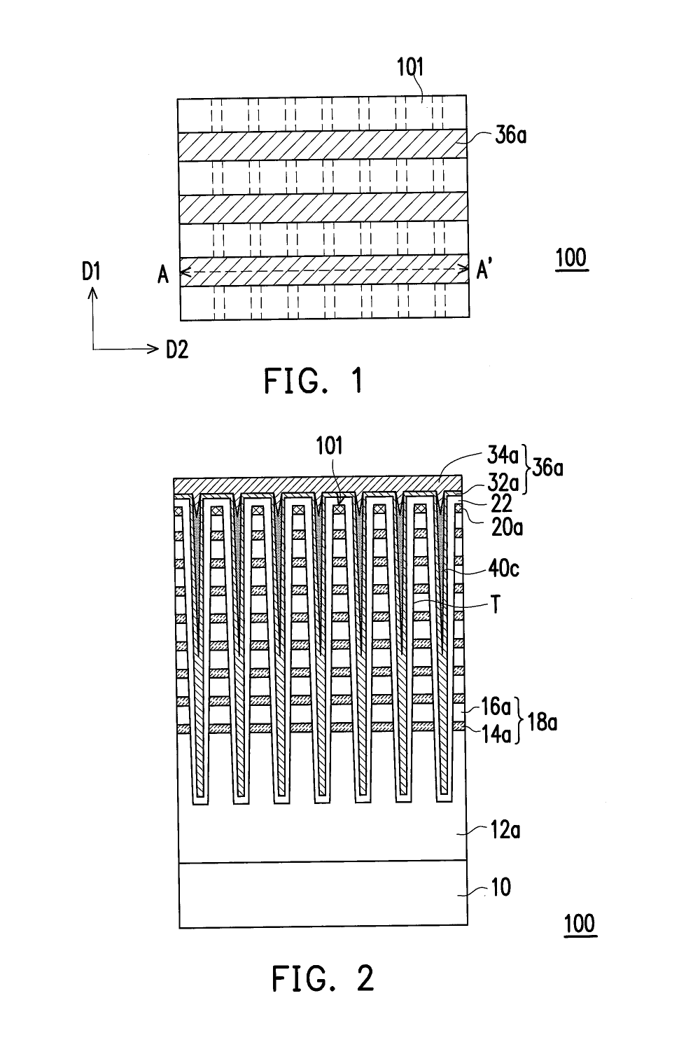

FIG. 1 is a schematic top view illustrating a semiconductor device 100 according to an embodiment of the invention. FIG. 2 is a schematic cross-sectional view illustrating the semiconductor device 100 along a A-A′ line of FIG. 1.

Referring to FIGS. 1 and 2, the semiconductor device 100 includes a substrate 10, a patterned dielectric layer 12a, a plurality of fin structures 101, a charge storage layer 22, a plurality of composite conductor layer 36a, and a plurality of filling pillars 40c. The substrate 10 may include a semiconductor material, an insulator material, a conductor material, or any combination of the foregoing materials. A material of the substrate 10 is a material composed of at least one selected from a group consisting of Si, Ge, SiGe, GaP, GaAs, SiC, SiGeC, InAs, and InP, or any physical structure suitable for a fabricating process of the invention, for example. The substrate 10 includes a single-layer structure or a multi-layer structure. In addition, a silicon on insulator (SOI) substrate may be used as the substrate 10. The substrate 10 is silicon or silicon germanium, for example.

The patterned dielectric layer 12a is disposed on the substrate 10. The dielectric layer 12a includes oxide, nitride, oxynitride, or a low dielectric constant material having a dielectric constant smaller than 4. In an embodiment, the dielectric layer 12a is a bottom oxide (BOX) layer, for example. A thickness of the dielectric layer 12a is in a range of 500 angstrom to 3000 angstrom, for example.

The plurality of fin structures 101 are disposed on the dielectric layer 12a. Each of the fin structures 101 extends along a first direction D1. A trench T is between two adjacent fin structures 101. The trench T may be in any length, width, or shape. The trench T may be a wide trench or a narrow trench. In an embodiment, a width of the trench T is in a range of 100 angstrom to 500 angstrom, for example, and a depth of the trench T is in a range of 0.1 micrometer to 3 micrometer, for example. In other words, the trench T has a higher aspect ratio. In an embodiment, the aspect ratio of the trench T is in a range of 10 to 40, for example. A cross section of the trench T may be in any shape, such as V shape, U shape, rhombus, or a combination thereof, for example. However, the invention is not limited thereto.

Each of the fin structures 101 is a stack structure, for example, including a plurality of conductor layers 14a and a plurality of dielectric layers 16a. The conductor layers 14a and the dielectric layers 16a are disposed alternately. In an embodiment, the conductor layer 14a is disposed on the dielectric layer 12a, and the dielectric layer 16a is disposed on the conductor layer 14a. However, the invention is not limited thereto.

In another embodiment, the dielectric layer 16a may also be disposed on the dielectric layer 12a. The conductor layers 14a and the dielectric layers 16a are alternately stacked upward on the substrate 10, so as to form the plurality of fin structures 101. In an embodiment, each of the conductor layers 14a and each of the dielectric layers 16a form a composite layer 18a, for example. In other words, each of the fin structures 101 includes a plurality of the composite layers 18a, for example. The dielectric layer 16a and the dielectric layer 12a may be formed of the same or different materials. A material of the dielectric layer 16a may include oxide, nitride, oxynitride, or a low dielectric constant material having a dielectric constant smaller than 4. A thickness of the dielectric layer 16a is in a range of 100 angstrom to 500 angstrom, for example. A material of the conductor layer 14a includes an undoped semiconductor or a doped semiconductor, such as polysilicon or doped polysilicon, for example. A thickness of the conductor layer 14a is in a range of 100 angstrom to 500 angstrom, for example. In an embodiment, the conductor layer 14a serves as a bit line or a word line of the semiconductor device 100, for example. Also, in this embodiment, the fin structure 101 is formed of polysilicon layers and oxide layers alternately disposed with respect to each other, for example.

Continuing to refer to FIG. 2, each of the fin structures 101 may further selectively include a hard mask layer 20a. The hard mask layer 20a is at the topmost layer of the fin structure 101, for example. However, the invention is not limited thereto. The hard mask layer 20a may be a single layer or multiple layers. A material of the hard mask layer 20a is silicon oxide, silicon nitride, or other suitable materials, for example. A thickness of the hard mask layer 20a is in a range of 100 angstrom to 500 angstrom, for example.

The charge storage layer 22 is disposed on the plurality of fin structures 101 and covers a top surface and sidewalls of each of the fin structures 101. A material of the charge storage layer 22 includes silicon nitride, silicon oxide, or a combination thereof The charge storage layer 22 may be a single layer or multiple layers. In an embodiment, the charge storage layer 22 is a single-layer silicon oxide layer, for example. In another embodiment, the charge storage layer 22 is a composite layer of oxide-nitride-oxide (ONO), for example. A thickness of the charge storage layer 22 is in a range of 100 angstrom to 400 angstrom, for example.

The plurality of composite conductor layers 36a are disposed on the charge storage layer 22. Each of the composite conductor layers 36a extends along a second direction D2. The second direction D2 is different from the first direction D1. The second direction D2 is orthogonal to the first direction D1, for example. Each of the composite conductor layers 36a covers a portion of the sidewalls and a portion of top surfaces of the fin structures 101. In an embodiment, each of the composite conductor layers 36a includes a conductor liner layer 32a and a conductor layer 34a. However, the invention is not limited thereto. In other embodiments, the composite conductor layer 36a may include three or more layers. The composite conductor layer 36a may serve as a word line or a bit line of the semiconductor device 100, for example. It should be noted that when the composite conductor layer 36a serves as a word line of the semiconductor device 100, for example, the conductor layer 14a disposed in the fin structure 101 serves as a bit line. Similarly, when the composite conductor layer 36a serves as a bit line of the semiconductor device 100, for example, the conductor layer 14a disposed in the fin structure 101 serves as a word line instead.

The conductor liner layer 32a is disposed on the charge storage layer 22. Each of the conductor liner layers 32a covers a portion of sidewalls and a portion of a top surfaces of the charge storage layer 22. In other words, each of the conductor liner layers 32a covers a portion of the sidewalls and a portion of the top surfaces of the fin structures 101. In an embodiment of the invention, the conductor liner layer 32a covering the portion of the sidewalls of the fin structures 101 is disposed in the trenches T, for example. Each of the conductor liner layers 32a extends along the second direction D2. A material of the conductor liner layer 32a includes polysilicon, N+ doped polysilicon, P+ doped polysilicon, a metal material, or a combination thereof, for example. A thickness of the conductor liner layer 32a is in a range of 50 angstrom to 300 angstrom, for example.

The conductor layer 34a is disposed on the conductor liner layer 32a, and covers the conductor liner layer 32a. Each of the conductor layers 34a is electrically connected with the conductor liner layer 32a on the portion of the top surfaces of the fin structures 101. In an embodiment, a portion of the conductor layer 34a extends into the trenches T, for example. A material of the conductor layer 34a includes polysilicon, N+ doped polysilicon, P+ doped polysilicon, a metal material, or a combination thereof, for example. A thickness of the conductor layer 34a is in a range of 100 angstrom to 1500 angstrom, for example. Each of the conductor layers 34a and each of the conductor liner layers 32a together serve as a word line or a bit line of the semiconductor device 100, for example.

The plurality of filling pillars 40c are disposed in the trenches T. In addition, each of the filling pillars 40c is disposed between each of the conductor liner layers 32a and each of the conductor layers 34a, for example. In other words, each of the filling pillars 40c is disposed inside each of the composite conductor layers 36a, for example. A surface of the filling pillar 40c may be flat or concave. In an embodiment, the surface of the filling pillar 40c is substantially aligned with a surface of the conductor liner layer 32a. In another embodiment, the surface of the filling pillar 40c is lower than the surface of the conductor liner layer 32a, for example. A material of the filling pillar 40c includes silicon nitride, silicon oxide, spin-on-glass (SOG) or a combination thereof. In addition, the filling pillar 40c may also be formed of any material having a better gap-filling ability than the composite conductor layer 36a (i.e. the conductor liner layer 32a or the conductor layer 34a).

It should be noted that since the filling pillar 40c in the trench T has a better gap-filling ability, it is less likely to produce a void in the trench T of the semiconductor device 100 of the invention, as compared with a conventional device where merely a conductor layer is filled in the trench. Also, when the trench T is a structure with a high aspect ratio, the filling pillar 40c in the trench T may further serve as a support pillar of the fin structure 101, thereby providing a higher resistance and preventing microbending of the fin structure 101.

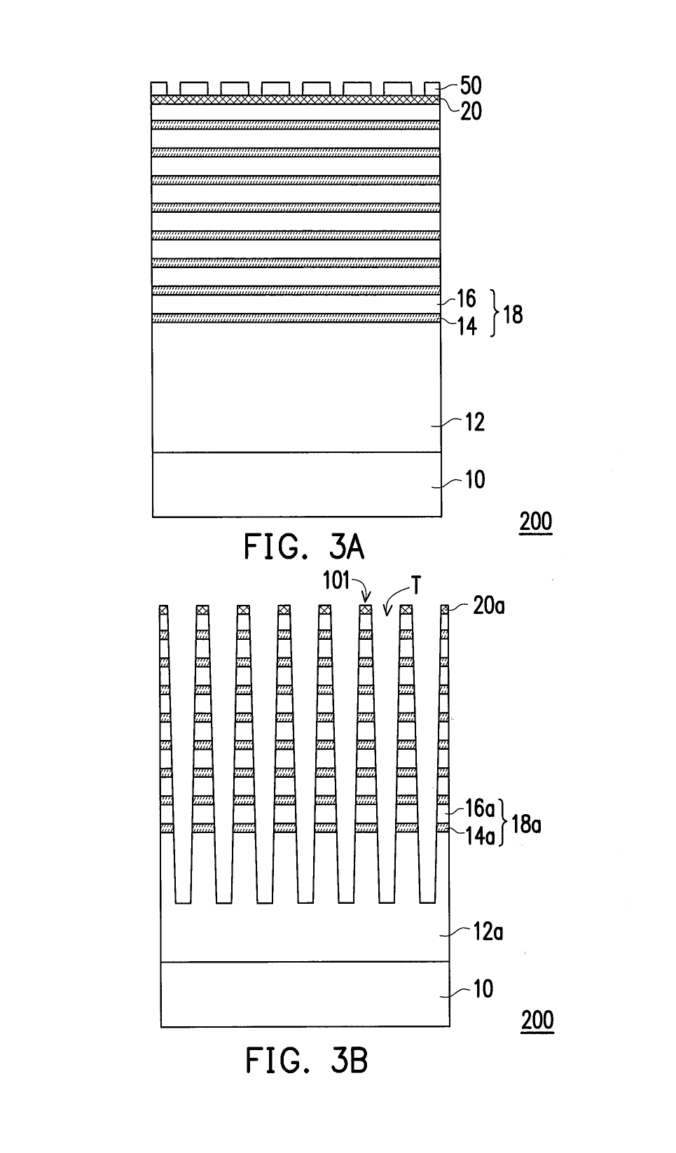

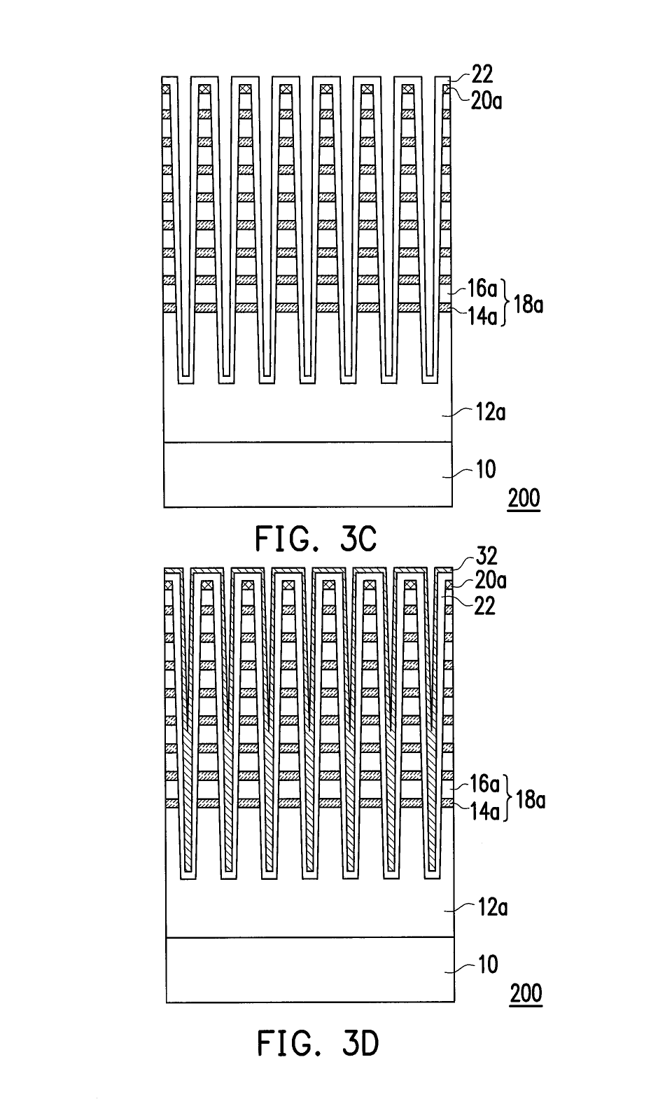

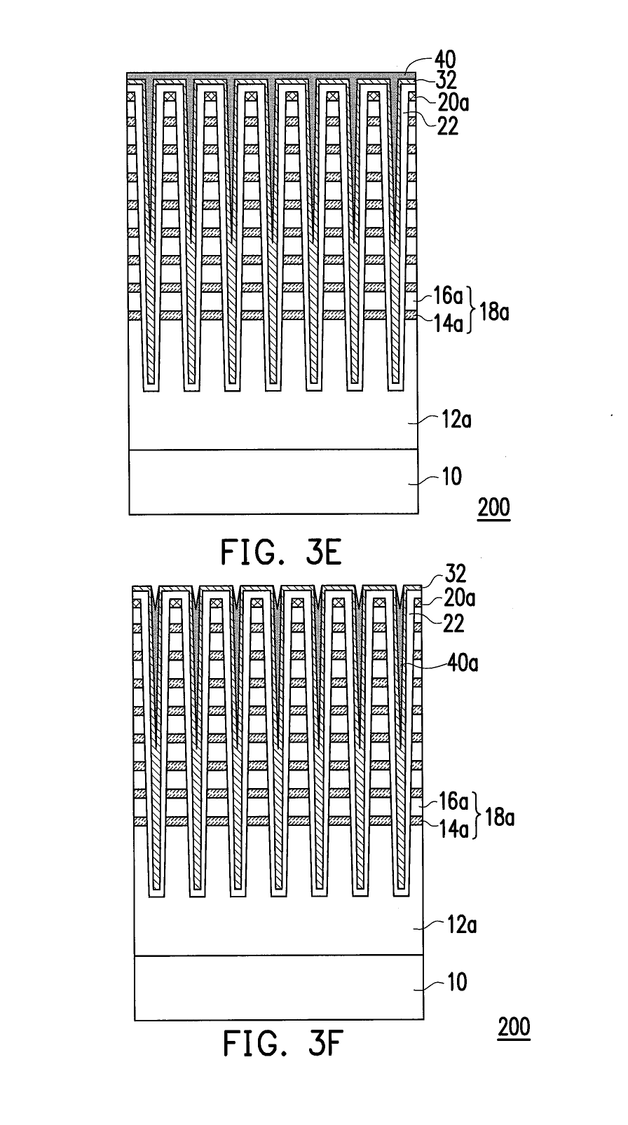

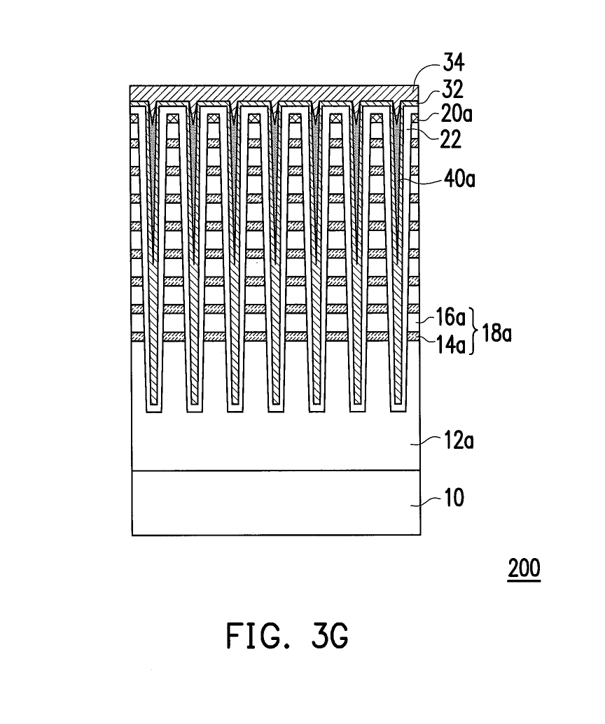

FIGS. 3A to 3G are schematic cross-sectional views illustrating a method of fabricating a semiconductor device 200 according to an embodiment of the invention.

Referring to FIG. 3A, the substrate 10 is provided. The material of the substrate 10 is already described above and thus is not repeated hereinafter. Next, the dielectric layer 12 is formed on the substrate 10. A material and a thickness of the dielectric layer 12 are the same as those of the dielectric layer 12a. A method of forming the dielectric layer 12 includes performing a thermal oxidation process or a chemical vapor deposition process, for example.

Next, a plurality of composite layers 18 are formed on the dielectric layer 12. A method of forming each of the composite layer 18 includes forming a conductor layer 14 on the dielectric layer 12, and then forming a dielectric layer 16 on the conductor layer 14. However, the invention is not limited thereto. In another embodiment, the method of forming the composite layers 18 includes forming a plurality of the conductor layers 14 and a plurality of the dielectric layers 16 in sequence on the dielectric layer 12. A material and a thickness of the conductor layer 14 are the same as those of the conductor layer 14a. A method of forming the conductor layer 14 includes performing a chemical vapor deposition process. A material and a thickness of the dielectric layer 16 are the same as those of the dielectric layer 16a. A method of forming the dielectric layer 16 includes performing a thermal oxidation process or a chemical vapor deposition process, for example.

Then, a hard mask 20 is formed on the topmost composite layer 18. A material and a thickness of the hard mask layer 20 are the same as those of the hard mask layer 20a. A method of forming the hard mask layer 20 includes performing a chemical vapor deposition process or a metal organic chemical vapor deposition (MOCVD) process. Then, a patterned photoresist layer 50 is formed on the hard mask layer 20.

Referring to FIGS. 3A and 3B at the same time, using the patterned photoresist layer 50 as a mask, an etching process is performed to form the plurality of fm structures 101 on the substrate 10 and form the plurality of trenches T between the fin structures 101. A method of performing the etching process to the semiconductor device 200 includes performing the etching process to the hard mask layer 20 using the patterned photoresist layer 50 as a mask, so as to transfer a pattern of the patterned photoresist layer 50 to the hard mask layer 20. The etching process includes performing an anisotropic etching process, such as a dry etching process, for example. The dry etching process may be a sputter etching process, a reactive ion etching process, etc. Next, the patterned photoresist layer 50 is removed. Then, using the patterned hard mask layer 20a as a mask, an etching process is performed to the plurality of dielectric layers 16, the plurality of conductor layers 14, and the dielectric layer 12, so as to form the plurality of fin structures 101 on the substrate 10.

Then, referring to FIG. 3C, the charge storage layer 22 is formed on the substrate 10. The charge storage layer 22 is conformally formed along with the top surfaces and the sidewalls of the fin structures 101. The material and the thickness of the charge storage layer 22 are the same as those described above. A method of forming the charge storage layer 22 includes performing a chemical vapor deposition process or a thermal oxidation process, for example.

Referring to FIG. 3D, a conductor material layer 32 is conformally formed on the charge storage layer 22. A material and a thickness of the conductor material layer 32 are the same as those of the conductor liner layer 32a, and are thus not repeated hereinafter. In an embodiment, the material of the conductor material layer 32 is polysilicon, for example. A method of forming the conductor material layer 32 includes performing a chemical vapor deposition process.

Next, referring to FIG. 3E, a filling material layer 40 is formed on the conductor material layer 32. The filling material layer 40 fills the trenches T and covers the conductor material layer 32. A material of the filling material layer 40 may be a dielectric material, such as silicon nitride, silicon oxide, or a combination thereof, for example. Alternatively, the material of the filling material layer 40 may be any material having a better gap-filling ability than the conductor material layer 32. A method of forming the filling material layer 40 includes performing an atomic layer deposition (ALD) process or a spin coating process. The spin coating process includes using the spin on glass (SOG) technology, for example.

Referring to FIG. 3F, using the conductor material layer 32 as a polishing or etching stop layer, the filling material layer 40 disposed on the top surfaces of the fin structures 101 is removed, so as to form the filling layer 40a in each of the trenches T. The filling layer 40a extends along the first direction D1 as shown in FIG. 1, for example. A method of removing the filling material layer 40 includes performing an etching back process or a chemical mechanical polishing process. Performing the etching back process may include performing a wet etching process or a dry etching process. In an embodiment, when the filling material layer 40 disposed on the top surfaces of the fin structures 101 is removed by performing the etching back process, a portion of the filling material layer 40 in the trenches T is also removed, such that the surface of the filling layers 40a subsequently formed becomes concave.

Then, referring to FIG. 3G, a conductor material layer 34 is formed on the substrate 10. The conductor material layer 34 covers the conductor material layer 32 and the filling layers 40a in the trenches T. In other words, each of the filling layers 40a is disposed between the conductor material layer 32 and the conductor material layer 34. A material and a thickness of the conductor material layer 34 are the same as those of the conductor layer 34a. A method of forming the conductor material layer 34 includes performing a chemical vapor deposition process.

Then, the conductor material layer 34, the conductor material layer 32, and the plurality of filling layers 40a are patterned to form the plurality of conductor layers 34a, the plurality of conductor liner layers 32a, and the plurality of filling pillars 40c on the substrate 10. At this stage, a top view of the semiconductor device 200 is as shown in FIG. 1, for example. Each of the conductor layers 34a and each of the conductor liner layers 32a extend along the second direction D2 in FIG. 1, for example. Also, each of the conductor liner layers 32a covers a portion of the sidewalls and a portion of the top surfaces of the fin structures 101. Each of the conductor layers 34a covers the conductor liner layer 32a and is electrically connected with the conductor liner layer 32a on the top surfaces of the fin structures 101. The plurality of filling pillars 40c are disposed in the trenches T, and disposed between each of the conductor liner layers 32a and each of the conductor layers 34a.

The method of fabricating the semiconductor device 200 described above only serves as an example for illustration, and does not serve to limit the invention. In other embodiments, the filling material layer 40 may be removed by performing a chemical mechanical polishing process, as described below.

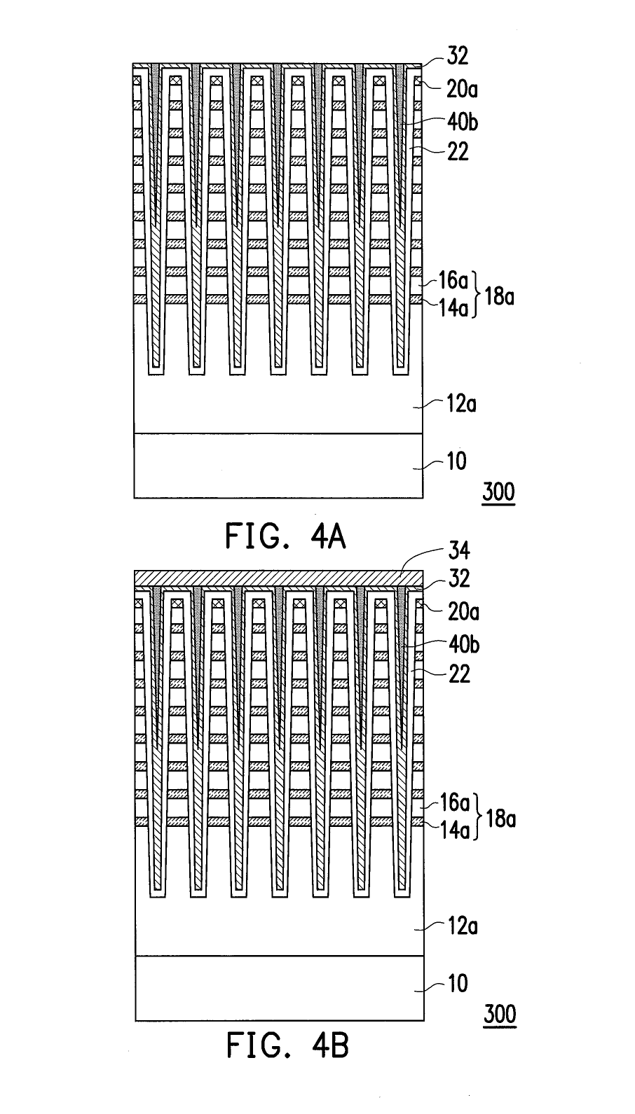

FIGS. 4A and 4B are schematic cross-sectional views illustrating a method of fabricating a semiconductor device 300 according to another embodiment of the invention.

Referring to FIG. 4A, after forming the filling material layer 40 on the conductor material layer 32, using the conductor material layer 32 as a polishing stop layer, the filling material layer 40 disposed on the top surfaces of the fin structures 101 is removed by performing a chemical mechanical polishing process to form a filling layer 40b in each of the trenches T. The filling layer 40b extends along the first direction D1 as shown in FIG. 1, for example. In this embodiment, a surface of the filling layer 40b is a flat surface, for example. In an embodiment, the surface of the filling layer 40b is aligned with the surface of the conductor material layer 32, for example.

Then, referring to FIG. 4B, the conductor material layer 34 is formed on the substrate 10. The conductor material layer 34 covers the conductor material layer 32 and the filling layers 40b in the trenches T. Then, the conductor material layer 34, the conductor material layer 32, and the plurality of filling layers 40b are patterned to form the plurality of conductor layers 34a, the plurality of conductor liner layers 32a, and the plurality of filling pillars 40c on the substrate 10.

Besides, in other embodiments, it is also plausible to conformally form the conductor material layer 34 on the conductor material layer 32 after forming the conductor material layer 32 and then form the filling layers in the trenches T. The methods of fabricating the semiconductor devices 200 and 300 described above only serve as examples for illustration, and the invention is not limited thereto. In other words, any method of fabricating a semiconductor device having a trench with a high aspect ratio including forming the filling layer in the trench is covered in the scope of the invention.

In view of the foregoing, in the invention, the conductor liner layer is formed in the trench having a high aspect ratio, and then the conductor layer covering the conductor liner layer is formed after filling the filling layer in the trench. Since the filling layer has a better gap-filling ability, it is less likely to produce a void when filling the filling layer in the trench. In addition, the filling layer may serve as a support pillar of the fin structure in the trench to provide a higher resistance, thereby preventing microbending of the fin structures between the trenches.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A semiconductor device, comprising:
a substrate;
a plurality of fin structures, disposed on the substrate, wherein a trench is between two adjacent fin structures;
a plurality of conductor liner layers, disposed on the substrate, wherein each of the conductor liner layers covers a portion of sidewalls and a portion of top surfaces of the fin structures;
a charge storage layer, disposed between the fin structures and the conductor liner layers;
a plurality of first conductor layers, disposed on the substrate, wherein the first conductor layers cover the conductor liner layers, and are electrically connected with the conductor liner layers on the portion of the top surfaces of the fin structures; and
a plurality of filling pillars, disposed in the trenches, wherein the filling pillars are disposed between the conductor liner layers and the first conductor layers.

2. The semiconductor device as claimed in claim 1, wherein a surface of the filling pillars is substantially aligned with a surface of the conductor liner layers.

3. The semiconductor device as claimed in claim 1, wherein a material of the filling pillars comprises silicon nitride, silicon oxide, spin-on-glass (SOG) or a combination thereof.

4. The semiconductor device as claimed in claim 1, wherein a material of the conductor liner layers and a material of the first conductor layers respectively comprise polysilicon, doped polysilicon, or a combination thereof.

5. The semiconductor device as claimed in claim 1, wherein each of the fin structures extends along a first direction, each of the conductor liner layers and each of the first conductor layers extend along a second direction, and the first direction is different from the second direction.

6. The semiconductor device as claimed in claim 1, wherein each of the fin structures comprises:
a plurality of second conductor layers; and
a plurality of dielectric layers alternately disposed with the second conductor layers.

7. The semiconductor device as claimed in claim 6, wherein the second conductor layers serve as bit lines or word lines.

8. The semiconductor device as claimed in claim 1, wherein the conductor liner layers and the first conductor layers together serve as word lines or bit lines.

9. A semiconductor device, comprising:
a substrate;
a plurality of fin structures, disposed on the substrate, wherein a trench is between two adjacent fin structures;
a plurality of composite conductor layers, disposed on the substrate, wherein each of the composite conductor layers covers a portion of sidewalls and a portion of top surfaces of the fin structures; and
a plurality of filling pillars, disposed in the trenches, wherein the filling pillars are disposed in each of the composite conductor layers.

10. The semiconductor device as claimed in claim 9, wherein a gap-filling ability of the filling pillars is better than a gap-filling ability of the composite conductor layers.

11. The semiconductor device as claimed in claim 9, wherein each of the composite conductor layers comprises:
a conductor liner layer, disposed on the substrate, wherein each conductor liner layer covers a portion of the sidewalls and a portion of the top surfaces of the fin structures; and
a first conductor layer, disposed on the conductor liner layer and electrically connected with the conductor liner layer.

12. The semiconductor device as claimed in claim 9, wherein each of the fin structures extends along a first direction, each of the composite conductor layers extends along a second direction, and the first direction is different from the second direction.

13. The semiconductor device as claimed in claim 9, wherein the composite conductor layers serve as word lines or bit lines.

14. A method of fabricating a semiconductor device, comprising:
providing a substrate;
forming a plurality of fin structures on the substrate, wherein a trench is between two adjacent fin structures;
forming a plurality of conductor liner layers on the substrate, wherein each of the conductor liner layers covers a portion of sidewalls and a portion of top surfaces of the fin structures;
forming a charge storage layer between the fin structures and the conductor liner layers;
forming a plurality of first conductor layers on the substrate, wherein the first conductor layers cover the conductor liner layers, and are electrically connected with the conductor liner layers on the portion of the top surfaces of the fin structures; and
forming a plurality of filling pillars in the trenches, wherein the filling pillars are disposed between the conductor liner layers and the first conductor layers.

15. The method of fabricating the semiconductor device as claimed in claim 14, wherein the steps of forming the conductor liner layers and the first conductor layers on the substrate and forming the filling pillars in the trenches comprise:
forming a first conductor material layer on the charge storage layer;
forming a plurality of filling layers in the trenches;
forming a second conductor material layer on the first conductor material layer and the filling layers; and
patterning the first conductor material layer, the filling layers and the second conductor material layer to form the conductor liner layers, the filling pillars and the first conductor layers.

16. The method of fabricating the semiconductor device as claimed in claim 15, wherein the step of forming the filling layers in the trenches comprises:
forming a filling material layer on the substrate, wherein the filling material layer covers the first conductor material layer; and
removing the filling material layer on the top surfaces of the fin structures to form the filling layers in the trenches.

17. The method of fabricating the semiconductor device as claimed in claim 16, wherein a method of removing the filling material layer on the top surfaces of the fin structures comprises performing an etching back process or a chemical mechanical polishing process.

18. The method of fabricating the semiconductor device as claimed in claim 16, wherein a method of forming the filling material layer comprises performing an atomic layer deposition process or a spin coating process.

19. The method of fabricating the semiconductor device as claimed in claim 14, wherein a material of the filling pillars comprises silicon nitride, silicon oxide, spin-on-glass (SOG) or a combination thereof.
